(19) United States
(12) Patent Application Publication
(10) Pub. No.: US 2026/0269477 A1
(43) Pub. Date: Sep. 10, 2026

(54) BURIED PATCH ANTENNA FOR LOW COST MMWAVE PHASED ARRAY DESIGN

(71) Applicant: JABIL INC., St. Petersburg, FL (US)

(72) Inventors: Ian Jeffery Timmins, St. Petersburg, FL (US); Babak Zarrin Rafie, St. Petersburg, FL (US); Youssef Faltone, St. Petersburg, FL (US); John Finnell, Swindon (GB)

(21) Appl. No.: 19/658,083

(22) Filed: Apr. 24, 2026

Related U.S. Application Data
(63) Continuation of application No. 18/694,779, filed on Sep. 16, 2022, now abandoned.
(60) Provisional application No. 63/261,476, filed on Sep. 22, 2021.

(51) Int. Cl. H01Q 9/04; H05K 1/11; H01Q 3/34

(52) U.S. Cl. CPC H01Q 9/0414; H05K 1/115; H01Q 3/34; H05K 2201/09618; H05K 2201/10098

(57) ABSTRACT

A mmWAVE phased array antenna that has particular application to be used in a 5G radio. The antenna includes a POCB structure having a plurality of dielectric layers and conductive layers. A beamforming IC is formed on one side of the PCB structure and a patch antenna radiating element is formed at an opposite side of the POCB structure from the beamforming IC, where one of the dielectric layers is formed over the radiating element so that the radiating element is curried.

### CROSS REFERENCE TO RELATED PATENT APPLICATIONS

This patent application claims the benefit of and priority to U.S. Pat. Appl. No. 18/694,779 filed on March 22, 2024, PCT Pat. Appl. No. PCT/US2022/076533 filed on September 16, 2022, and the Provisional U.S. Pat. Appl. No. 63/261,476, filed on September 22, 2021, the entire contents of each of which are incorporated herein by reference.

### TECHNICAL FIELD

This disclosure relates generally to a millimeter wave (mmWave) antenna and, more particularly, to a mmWave phased array antenna including a buried patch antenna radiating element.

### BACKGROUND

Electrically Cellular telecommunications companies began deploying fifth generation (5G) radio technology standard for cellular networks in 2019. The 5G radio standard utilizes a higher frequency spectrum than previous generations of commercial communications technologies. MmW phased array antennas are being designed and developed for the 5G protocol that provides increased performance over 4G systems while also reducing costs. 5G mmWave antennas typically require precise manufacturing of printed circuit boards (PCBs) because antenna features on the order of a wavelength are at the limits of manufacturing tolerance of the PCB fabrication process. One of the most challenging RF circuits in the PCB design are patch antennas that combine to create the phased array antenna.

There are number of considerations when fabricating a mmWave patch antenna. Particularly, the dimensions of the patch antenna and the supporting circuits need to be compatible with PCB manufacturing tolerance. Also, the solder mask tends to be a material where the thickness and dielectric constant vary considerably more than the thickness and dielectric constant of the high performance PCB materials used for mmWave applications. Further, the finishes used on exposed copper for conventional circuits boards at mmWave is problematic in the sense that electroless nickel immersion gold (ENIG) produces increased levels of signal loss as the RF skin depth penetrates the finish, and is thus not desirable, organic solderability preservatives (OSP) leaves the copper exposed, and over long life of the antenna will result in oxidation of the copper, and possible changes in the dimensions of the RF circuits due to this oxidation, as well as degraded aesthetics, and silver and gold plating over copper are expensive alternatives, and are not suitable for high volume low cost manufacturing.

### SUMMARY

The following discussion discloses and describes a mmWave phased array antenna that has particular application to be used in a 5G radio. The antenna includes a printed circuit board (PCB) structure having a plurality of dielectric layers and conductive layers. A beamforming integrated circuit (IC) is formed on one side of the PCB structure and a patch antenna radiating element is formed at an opposite side of the PCB structure from the beamforming IC, where one of the dielectric layers is formed over the radiating element so that the radiating element is buried.

Additional features of the disclosure will become apparent from the following description and appended claims, taken in conjunction with the accompanying drawings.

### DESCRIPTION OF THE DRAWINGS

FIG. 1 is a profile view of a mmWave phased array antenna including a buried patch antenna radiating element; and

FIG. 2 is an isometric type view of the mmWave phased array antenna.

### DESCRIPTION OF AN EMBODIMENT

The following discussion of the embodiments of the disclosure directed to a mmWave phased array antenna including a buried patch antenna radiating element is merely exemplary in nature, and is in no way intended to limit the disclosure or its applications or uses. For example, the discussion herein refers to the antenna as being part of a phased array antenna for a 5G radio. However, as will be appreciated by those skilled in the art, the antenna will have other applications.

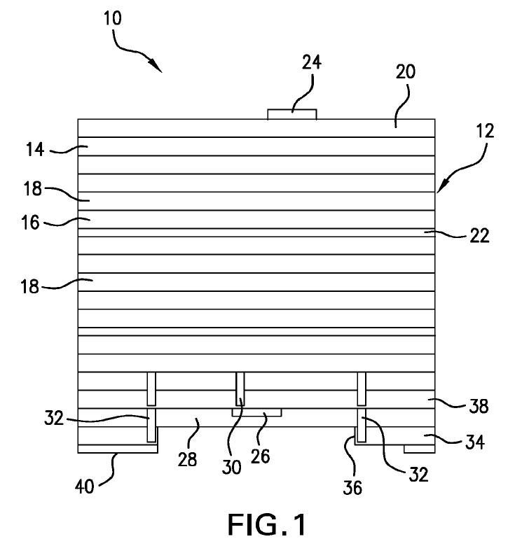

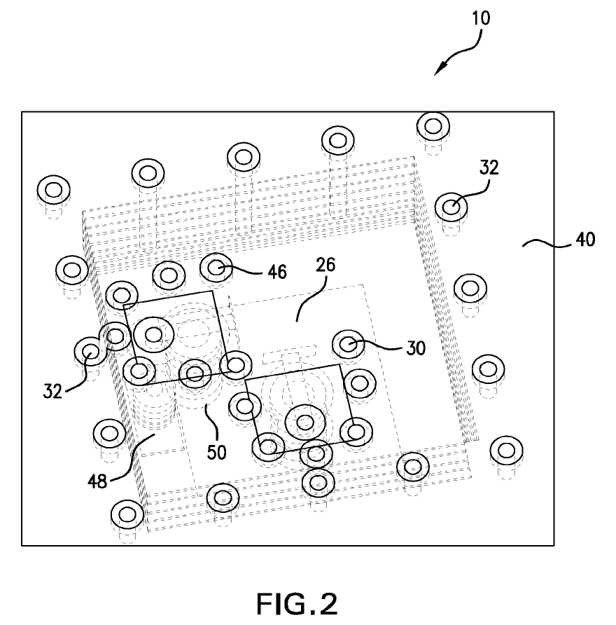

FIG. 1 is a profile view and FIG. 2 is an isometric type view of a mmWave phased array antenna 10, where the antenna 10 can be part of a 5G radio. The antenna 10 includes a PCB structure 12 having a stack of layers 14 including core dielectric layers 16, dielectric insulating prepreg layers 18, copper layers 20 and a feed layer 22, where the number, thickness, configuration, material, etc. of the layers 14 would be designed for a particular antenna as would be well understood by those skilled in the art. A beamforming IC 24 is provided at one side of the PCB structure 12 and includes the circuitry necessary for beam phase combining and beam steering for multiple radiating elements in the phased array antenna 10 in a manner well understood by those skilled in the art. Multiple beamforming ICs would be provided for a phased array antenna. A patch antenna radiating element 26 is formed at an opposite side of the PCB structure 12 from the beamforming IC 24 on a dielectric layer 38 and would be one of many radiating elements formed on the PCB structure 12 to provide the phased array antenna 10, where the radiating element 26 could be formed of 1/2 oz. copper. A thin dielectric layer 28 is formed over the radiating element 26 so that the radiating element 26 is a buried radiating element, where the dielectric layer 28 protects the radiating element 26 and is electrically small enough to not significantly attenuate the radiated signal. Suitable signal vias, represented by via 30, are formed through the layers 14 to provide a signal path between the beamforming IC 24 and the radiating element 26. A suitable number of fencing vias 32 are formed in the layers 14 around the radiating element 26 to prevent capacitive signal coupling between the radiating element 26 and other radiating elements. A dielectric layer 34 is formed on the dielectric layer 28 and is etched to provide an aperture 36 to allow propagation of the radiated signal from the element 26. An outer ground plane 40 is formed on the dielectric layer 34 and can be plated with ENIG.

FIG. 2 shows a number of microvias 46 in the layers 28 and 34 that allow for the elimination of a stub to the layer 34 because the radiating element 26 sits one layer back, and the variation in plating of the microvias and feed structure is not subject to the variability of plating up the layers towards the end of the PCB manufacturing process. FIG. 2 also shows a localized patch feed 48 to the radiating element 26, which is also located one layer inside the PCB structure 12 from the bottom, and a transition 50 from the feed layer 22.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. An antenna containing structure comprising:
a printed circuit board (PCB) structure including a plurality of dielectric layers and conductive layers sandwiched between opposing first and second major surfaces;
a beamforming integrated circuit (IC) positioned on the first major surface of the PCB structure;
a patch antenna radiating element positioned on the second major surface of the PCB structure, wherein one of the dielectric layers is positioned on the second major surface and over the radiating element burying the radiating element in the sandwiched layers; and
a via through the sandwiched layers and coupling the beamforming IC to the antenna radiating element.

2. The antenna containing structure according to claim 1
further comprising fencing vias through at least one sandwiched dielectric layer and peripherally around the patch antenna radiating element at least partially isolating the radiating element.

3. The antenna containing structure according to claim 1
wherein another one of the dielectric layers is positioned over the one dielectric layer positioned on the second major surface and over the radiating element, said another one of the dielectric layers having an aperture in front of the patch antenna radiating element.

4. The antenna containing structure according to claim 3
further comprising fencing vias within the one dielectric layer and the another one of dielectric layers and peripherally around the patch antenna radiating element at least partially isolating the radiating element.

5. The antenna containing structure according to claim 3
wherein one of the conductive layers is positioned over the another one of the dielectric layers opposite to the one dielectric layer.

6. The antenna containing structure according to claim 1 wherein the antenna is containing structure includes a phased array antenna.

7. The antenna containing structure according to claim 6 wherein the phased array antenna is part of a 5G radio.

8. A phased array antenna containing structure comprising:
a printed circuit board (PCB) structure including a plurality of dielectric layers and conductive layers sandwiched between opposing first and second major surfaces;
a beamforming integrated circuit (IC) positioned on the first major surface of the PCB structure;
a patch antenna radiating element positioned on the second major surface of the PCB structure, wherein one of the dielectric layers is positioned on the second major surface and over the radiating element burying the radiating element in the sandwiched layers and another one of the dielectric layers is positioned over the one dielectric layer positioned on the second major surface and over radiating element, said another one of the dielectric layers having an aperture in front of the patch antenna radiating element; and
a via through the sandwiched layers and coupling the beamforming IC to the radiating element.

9. The antenna containing structure according to claim 8
further comprising fencing vias positioned through the one dielectric layer and the another one of the dielectric layers peripherally around the patch antenna radiating element at least partially isolating the radiating element.

10. The antenna containing structure according to claim 9 wherein one of the conductive layers is positioned over the another one of the dielectric layers opposite to the one dielectric layer.

11. The antenna containing structure according to claim 8 wherein the antenna containing structure is part of a 5G radio.

12. The antenna containing structure according to claim 1 further comprising a plurality of micro vias through at least two of the sandwiched layers.

13. The antenna containing structure according to claim 2 further comprising a plurality of micro vias through at least two of the sandwiched layers
